(19) United States
(12) Patent Application Publication
(10) Pub. No.: US 2014/0042522 A1
(43) Pub. Date: Feb. 13, 2014

(54) RF LDMOS DEVICE AND FABRICATION METHOD THEREOF

(71) Applicant: SHANGHAI HUA HONG NEC ELECTONICS CO, LTD., Shanghai (CN)

(72) Inventors: Juanjuan Li, Shanghai (CN); Shengan Xiao, Shanghai (CN); Wensheng Qian, Shanghai (CN); Feng Han, Shanghai (CN); Pengliang Ci, Shanghai (CN)

(73) Assignee: SHANGHAI HUA HONG NEC ELECTONICS CO, LTD., Shanghai (CN)

(21) Appl. No.: 13/964,678

(22) Filed: Aug. 12, 2013

(30) Foreign Application Priority Data
Aug. 13, 2012 (CN) 201210287201.5

(51) Int. Cl. H01L 29/78; H01L 29/66

(52) U.S. Cl. CPC H01L 29/7816; H01L 29/66681
USPC 257/328; 438/286

(57) ABSTRACT

A radio frequency (RF) laterally diffused metal oxide semiconductor (LDMOS) device includes a substrate, a p-type epitaxial layer, a p-type well, a lightly doped n-type drain region, a gate oxide layer, a polysilicon gate, a dielectric layer and a Faraday shield. The Faraday shield includes: a horizontal portion covering a portion of the polysilicon gate and isolated from the polysilicon gate by the dielectric layer; a step-like portion with at least two steps covering a portion of the lightly doped n-type drain region and isolated from the lightly doped n-type drain region by the dielectric layer; and a vertical portion connecting the horizontal portion with the step-like portion and isolated from the polysilicon gate and the lightly doped n-type drain region by the dielectric layer. A method of fabricating such an RF LDMOS device is also disclosed.

### CROSS-REFERENCES TO RELATED APPLICATIONS

This application claims the priority of Chinese patent application number 201210287201.5, filed on Aug. 13, 2012, the entire contents of which are incorporated herein by reference.

### TECHNICAL FIELD

The present invention relates in general to semiconductor technology, and in particular, to a radio frequency (RF) laterally diffused metal oxide semiconductor (LDMOS) device and fabrication methods thereof.

### BACKGROUND

Radio frequency (RF) laterally diffused metal oxide semiconductor (LDMOS) device is a new generation integrated solid microwave power semiconductor device. It is a product of the combination of semiconductor integrated circuit technology and microwave electronics technology and has a variety of advantages such as high linearity, high gain, high voltage endurance, great output power, good thermal stability, high efficiency, good broadband matching property and high compatibility with MOS technology. Moreover, it is commercially available at a much lower price than gallium-arsenide (GaAs) devices. All of these advantages make the RF LDMOS device a very competitive power device that has been widely used as a power amplifier for Global System for Mobile communications (GSM), Personal Communications Service (PCS) and Wideband Code Division Multiple Access (W-CDMA) base stations and in wireless broadcasting, nuclear magnetic resonance (NMR) and many other applications.

To design a good RF LDMOS device, it is generally required that the device has both a low on-resistance and a high breakdown voltage. In addition, as a gate-drain capacitance of the device determines its cut-off frequency, it is also required to have a gate-drain capacitance as low as applicable. A high breakdown voltage ensures a high operational stability for the device. For example, an RF LDMOS having a working voltage of 50 V is typically required to have a breakdown voltage of not lower than 110 V. Moreover, the on-resistance Rdson of an RF LDMOS device is directly related to its output power, gain and other properties.

FIG. 1 shows a common RF LDMOS device. In the device, a p-type substrate 1 is covered by a p-type epitaxial 10. A p-type well 11 is formed in a left portion of the p-type epitaxial 10, and a lightly doped n-type drain region 12 is formed in a right portion of the p-type epitaxial 10. The p-type well 11 is not in contact with the lightly doped n-type drain region 12.

Moreover, a heavily doped n-type source region 24 is formed in an upper portion of the p-type well 11.

A heavily doped n-type drain region 21 is formed in a right portion of the lightly doped n-type drain region 12.

Both the heavily doped n-type source region 24 and the heavily doped n-type drain region 21 have a higher n-type dopant concentration than the lightly doped n-type drain region 12.

A contact column 13 is connected to a left edge of the p-type well 11.

The contact column 13 is further extending downwards into the p-type substrate 1.

A heavily doped p-type region 22 is formed in an upper portion of the p-type well 11 left to the heavily doped n-type source region 24. The heavily doped p-type region 22 is connected to the contact column 13 and has a higher p-type dopant concentration than the p-type well 11.

A gate oxide layer 14 is covering both an upper portion of the p-type well 11 right to the heavily doped n-type source region 24 and a portion of the p-type epitaxial 10 between the p-type well 11 and the lightly doped n-type drain region 12.

A polysilicon gate 15 is covering the gate oxide layer 14.

An oxide layer 16 is covering both the polysilicon gate 15 and a left portion of the lightly doped n-type drain region 12.

Furthermore, a right portion of the oxide layer 16 is covered by a Faraday shield 17.

In a common RF LDMOS device, a lightly doped drift (LDD) region is formed at the end of the drain region to provide a high breakdown voltage BV of the device. However, the relatively low doping concentration of the lightly doped n-type drain region 12 will lead to a high on-resistance Rdson of the device. The Faraday shield 17 functions to reduce the feedback gate-drain capacitance Cgd. In addition, as the Faraday shield 17 is kept at zero electric potential during the operation of the device, it can further function as a field plate. Thus, modification of its length or the thickness of the underlying dielectric layer can result in a certain reduction of a surface electric field and hence an increase in the breakdown voltage of the device. Additionally, the length or thickness modification can also facilitate the prevention of hot carrier injection (HCl).

As shown in FIG. 1, a common Faraday shield 17 is comprised of a “step-like” single metal layer including a horizontal portion 171, a step-like portion 172 and a vertical portion 173. The vertical portion 173 connects the horizontal portion 171 and the step-like portion 172. The horizontal portion 171 is at upper left to the vertical portion 173 and the step-like portion 172 is at lower right to the vertical portion 173. The vertical portion 173 is right to the polysilicon gate 15. A left portion of the horizontal portion 171 is above the polysilicon gate 15 and the step-like portion 172 is situated above the lightly doped n-type drain region 12. A portion of the dielectric layer 16 is sandwiched between the Faraday shield 17 and the polysilicon gate 15 and the rest portion is sandwiched between the Faraday shield 17 and the lightly doped n-type drain region 12. Additionally, the step-like portion 172 has at least one step portion. It is very hard for an RF LDMOS device employing a Faraday shield comprised of a single metal layer with such a design to achieve a very high breakdown voltage.

Currently, in order to obtain an RF LDMOS device with a wider safe operating area (SOA), which are suited for high-voltage applications (i.e., at a working voltage of 50V), manufacturers generally adopt a Faraday shield with two or more metal layers. As shown in FIGS. 2 and 3, in such a Faraday shield, the first metal layer has the same configuration with the one of FIG. 1 and other metal layers are sequentially formed at the upper right of the first metal layer. Each two adjacent metal layers are isolated by a dielectric layer 16. An RF LDMOS device employing such a Faraday shield comprised of two or more metal layers has a high breakdown voltage, generally of about 120 V. However, on the other hand, as two (or more) metal layers are formed in the fabrication of such an RF LDMOS device, the fabrication is required to include at least two dielectric layer deposition processes, at least two metal layer deposition processes and at least two metal etching processes and is hence very complicated.

### SUMMARY OF THE INVENTION

The present invention is directed to provide an RF LDMOS device having a high breakdown voltage and can be fabricated in a simple way.

To achieve the above objective, there is provided a radio frequency (RF) laterally diffused metal oxide semiconductor (LDMOS) device. The RF LDMOS device includes: a substrate; a p-type epitaxial layer on the substrate; a p-type well in a first portion of the p-type epitaxial layer; a lightly doped n-type drain region in a second portion of the p-type epitaxial layer and separated from the p-type well; a gate oxide layer covering a portion of the p-type well and a portion of the p-type epitaxial layer between the p-type well and the lightly doped n-type drain region; a polysilicon gate covering the gate oxide layer; a dielectric layer covering the polysilicon gate and a portion of the lightly doped n-type drain region; and a Faraday shield formed of a single metal layer and comprising: a horizontal portion covering a portion of the polysilicon gate and isolated from the polysilicon gate by the dielectric layer; a step-like portion covering a portion of the lightly doped n-type drain region and isolated from the lightly doped n-type drain region by the dielectric layer, the step-like portion having a step-like top surface with at least two step portions and a height of the at least two step portions increasing progressively in a direction from the p-type well to the lightly doped n-type drain region; and a vertical portion connecting the horizontal portion with the step-like portion, the vertical portion being isolated from the polysilicon gate and the lightly doped n-type drain region by the dielectric layer.

In one specific embodiment, the RF LDMOS device may further include: a heavily doped n-type source region in an upper portion of the p-type well; and a heavily doped n-type drain region in the lightly doped n-type drain region and proximate to an edge of the lightly doped n-type drain region that is farther from the gate oxide layer, wherein both the heavily doped n-type source region and the heavily doped n-type drain region have an n-type dopant concentration higher than an n-type dopant concentration of the lightly doped n-type drain region.

In another embodiment, the step-like portion has a step-like top surface with two step portions and a height of the two step portions increases progressively in a direction from the p-type well to the lightly doped n-type drain region.

In another embodiment, the step-like portion has a step-like top surface with three step portions and a height of the three step portions increases progressively in a direction from the p-type well to the lightly doped n-type drain region.

In another embodiment, a portion of the dielectric layer between a first step portion nearest to the gate oxide layer and the lightly doped n-type drain region has a thickness of 10 nm to 800 nm, wherein a portion of the dielectric layer between a former step portion and the lightly doped n-type drain region has a thickness of 10 nm to 100 nm smaller than a thickness of a portion of the dielectric layer between a latter step portion and the lightly doped n-type drain region, and wherein each step portion of the step-like portion has a length of 0.01 μm to 3 μm.

To achieve the above objective, there is also provided a method of fabricating a radio frequency (RF) laterally diffused metal oxide semiconductor (LDMOS) device. The method includes the steps of: providing a substrate; forming a p-type epitaxial layer over the substrate; forming a p-type well in a first portion of the p-type epitaxial layer; forming a lightly doped n-type drain region in a second portion of the p-type epitaxial layer, the lightly doped n-type drain region being separated from the p-type well; forming a gate oxide layer and a polysilicon gate, the gate oxide layer covering a portion of the p-type well and a portion of the p-type epitaxial layer between the p-type well and the lightly doped n-type drain region, the polysilicon gate covering the gate oxide layer; depositing a dielectric layer over the polysilicon gate and a portion of the lightly doped n-type drain region; and forming a Faraday shield, the Faraday shield including: a horizontal portion covering a portion of the polysilicon gate and isolated from the polysilicon gate by the dielectric layer; a step-like portion covering a portion of the lightly doped n-type drain region and isolated from the lightly doped n-type drain region by the dielectric layer, the step-like portion having a step-like top surface with at least two step portions and a height of the at least two step portions increasing progressively in a direction from the p-type well to the lightly doped n-type drain region; and a vertical portion connecting the horizontal portion with the step-like portion, the vertical portion being isolated from the polysilicon gate and the lightly doped n-type drain region by the dielectric layer.

The Faraday shield formed of a single metal layer with a step-like shape enables the RF LDMOS device of the present invention to have a similar performance to an RF LDMOS device employing a Faraday shield formed of multiple metal layers in attaining a high breakdown voltage while keeping the on-resistance and gate-drain capacitance unchanged. Moreover, compared to the complicated fabrication of the Faraday shield formed of multiple metal layers, the Faraday shield formed of a single metal layer with a step-like shape can be fabricated in a simpler way which results in the reduction of at least one dielectric layer deposition process, one metal layer deposition process and one metal etching processes. Therefore, the present invention not only ensures a high breakdown voltage and a high reliability for an RF LDMOS device, but also enables the device to be fabricated in a simple way.

### BRIEF DESCRIPTION OF THE DRAWINGS

Accompanying drawings for further describing principles of the present invention will be briefly described below. What is depicted by the accompanying drawings taken as reference in the following detailed description are only several non-limiting exemplary embodiments of the present invention. Those skilled in the art can make other similar drawings in light of the accompanying drawings without exerting creative efforts.

FIG. 1 shows a schematic illustration of an existing RF LDMOS including a common Faraday shield comprised of a single metal layer.

FIG. 2 shows a schematic illustration of an existing RF LDMOS including a Faraday shield comprised of two metal layers.

FIG. 3 shows a schematic illustration of an existing RF LDMOS including a Faraday shield comprised of three metal layers.

FIG. 4 shows a schematic illustration of an RF LDMOS including a Faraday shield having a step-like portion with two step portions in accordance with one embodiment of the present invention.

FIG. 5 shows a schematic illustration of an RF LDMOS including a Faraday shield having a step-like portion with three step portions in accordance with one embodiment of the present invention.

FIG. 6 depicts an RF LDMOS device fabrication method in accordance with Embodiment 3 of the present invention.

FIG. 7 depicts an RF LDMOS device fabrication method in accordance with Embodiment 4 of the present invention.

FIG. 8 depicts electric field intensity curves of a common Faraday shield comprised of a single metal layer, a common Faraday shield comprised of two metal layers and a Faraday shield comprised of a step-like metal layer with two step portions of the present invention.

FIG. 9 depicts electric field intensity curves of a common Faraday shield comprised of three metal layers and a Faraday shield comprised of a step-like metal layer with three step portions of the present invention.

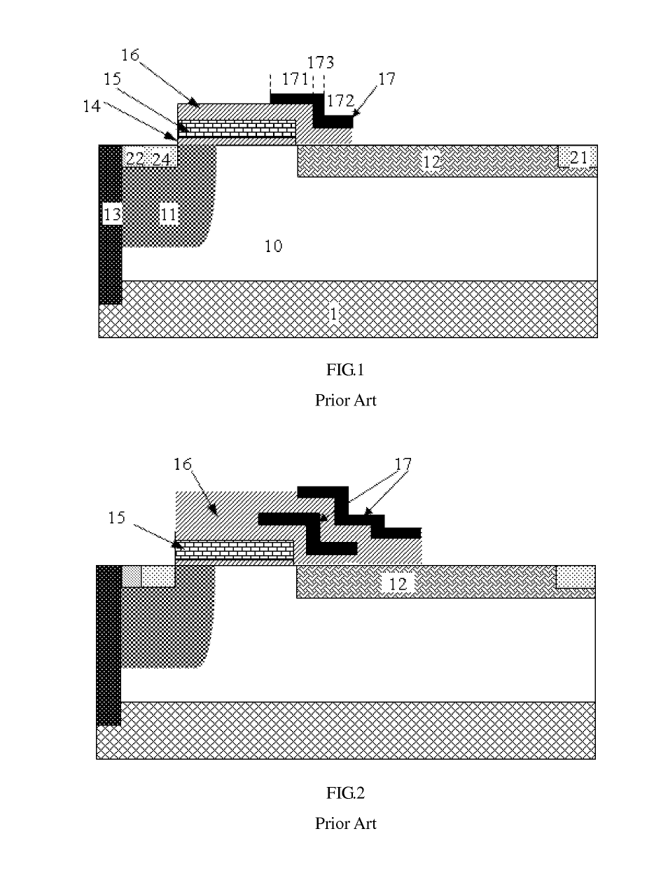

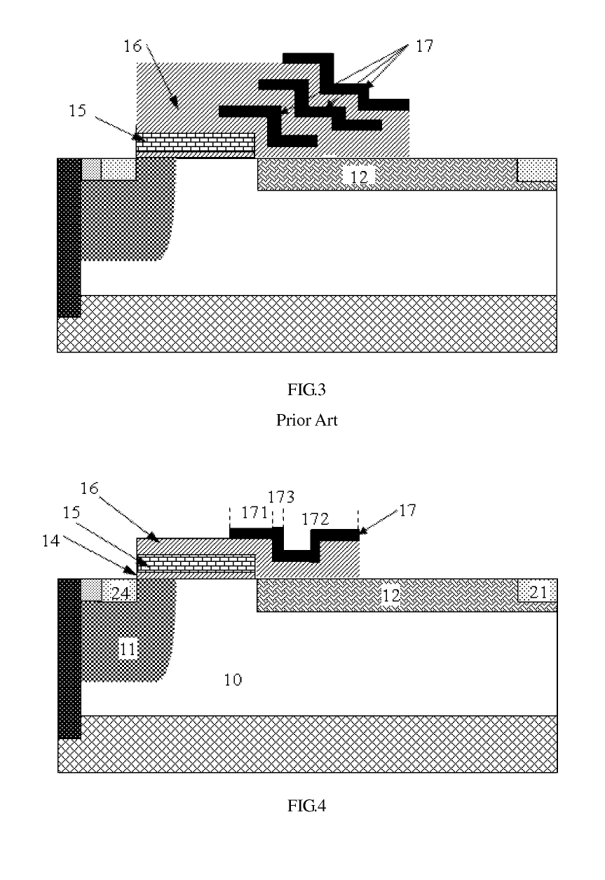

### DETAILED DESCRIPTION OF THE INVENTION

Exemplary embodiments are described in detail below in conjunction with the accompanying drawings so that this disclosure will be thorough and fully understood. The embodiments described herein are only some exemplary embodiments rather than all embodiments of the present invention. All other embodiments made without exerting creative efforts by those skilled in the art in light of principles of the exemplary embodiments are considered to be within the scope of the present invention.

### Embodiment 1

FIG. 4 shows an RF LDMOS device constructed in accordance with this embodiment. The RF LDMOS device includes a p-type epitaxial layer 10. A lightly doped n-type drain region 12 is formed in a right portion of the p-type epitaxial 10 and a p-type well 11 is formed in a left portion of the p-type epitaxial 10. The p-type well 11 is not in contact with the lightly doped n-type drain region 12. A gate oxide layer 14 covers a portion of the p-type epitaxial layer 10 between the p-type well 11 and the lightly doped n-type drain region 12 and covers a right portion of the p-type well 11. A polysilicon gate 15 is covering the gate oxide layer 14. A dielectric layer 16 (e.g., a silicon oxide layer) covers a top surface and a side face of the polysilicon gate 15 and a left portion of the lightly doped n-type drain region 12. A Faraday shield 17 covers a right portion of the oxide layer 16.

The Faraday shield 17 is comprised of a single metal layer including a horizontal portion 171, a step-like portion 172 and a vertical portion 173. The vertical portion 173 is right to the polysilicon gate 15 and has its upper and lower ends joined with a right end of the horizontal portion 171 and a left end of the step-like portion 172, respectively. The horizontal portion 171 has its left end situated above the polysilicon gate 15. The step-like portion 172 is situated above the lightly doped n-type drain region 12. A portion of the dielectric layer 16 is sandwiched between the Faraday shield 17 and the polysilicon gate 15 and the rest portion is sandwiched between the Faraday shield 17 and the lightly doped n-type drain region 12. The step-like portion 172 has a step-like shape which increases its height from the left to the right.

The step-like portion 172 has a plurality of step portions. FIG. 4 shows an embodiment of the step-like portion 172 which has two step portions increasing their height from the left to the right, whilst FIG. 5 shows another embodiment of the step-like portion 172 which has three step portions also increasing their height from the left to the right.

Preferably, a portion of the dielectric layer 16 between the first step portion that is nearest to the polysilicon gate 15 and the lightly doped n-type drain region 12 has a thickness T0 of 10 nm to 800 nm; a difference between the thickness TO and a thickness of a portion of the dielectric layer 16 between the second step portion and the lightly doped n-type drain region 12 is of 10 nm to 100 nm; each step portion has a length (e.g., in the embodiment of FIG. 5, the first step portion has a length L1, the second step portion has a length L2, and the third step portion has a length L3) of 0.01 μm to 3 μm; a distance S2 between the left edge of the step-like portion 172 and the nearest edge of the polysilicon gate 15 is of 0.001 μm to 0.3 μm; and the portion of the horizontal portion 171 that is right above the polysilicon gate 15 has a length Si of 0 μm to 1 μm.

### Embodiment 2

Referring to FIGS. 4 and 5, based on the device of Embodiment 1, an RF LDMOS device in this embodiment further includes a heavily doped n-type source region 24 in an upper portion of the p-type well 11 and a heavily doped n-type drain region 21 in a right portion of the lightly doped n-type drain region 12.

Both the heavily doped n-type drain region 21 and the heavily doped n-type source region 24 have a higher n-type dopant concentration than the lightly doped n-type drain region 12.

In this embodiment, a gate oxide layer 14 covers a portion of the p-type well 11 right to the heavily doped n-type source region 24 and a portion of the p-type epitaxial layer 10 between the p-type well 11 and the lightly doped n-type drain region 12.

Moreover, a polysilicon gate 15 is covering the gate oxide layer 14.

### Embodiment 3

In this embodiment, the RF LDMOS device of Embodiment 1 is fabricated in a method including the following steps.

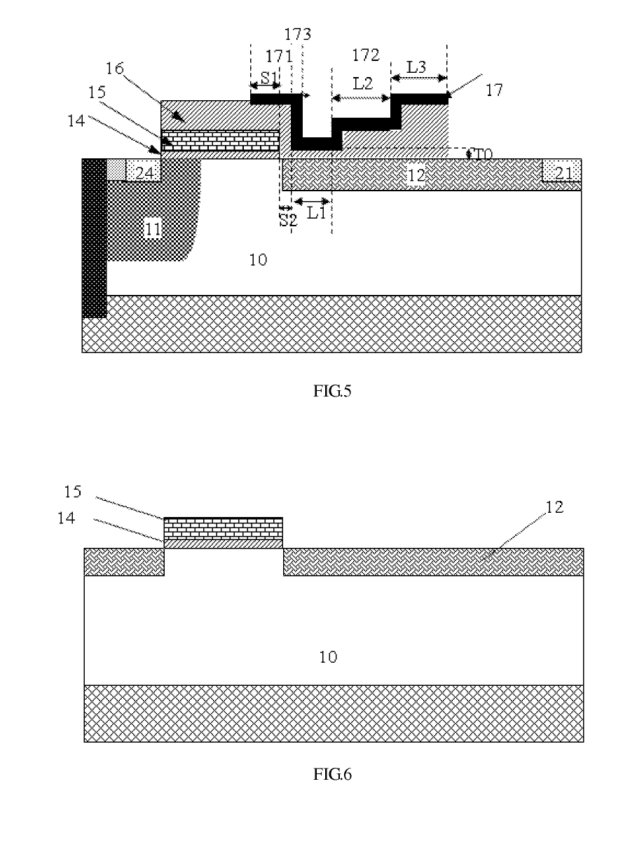

Turning now to FIG. 6, in a first step of the method, the lightly doped n-type drain region 12 is first formed in a right portion of the p-type epitaxial layer 10. Next, the p-type well 11 is formed in a left portion of the p-type epitaxial layer 10. After that, the gate oxide layer 14 is formed which covers a portion of the p-type epitaxial layer 10 between the p-type well 11 and the lightly doped n-type drain region 12 and covers a right portion of the p-type well 11, and then the polysilicon gate 15 covering the gate oxide layer 14 is formed.

In a second step, a dielectric layer 16 (e.g., a silicon oxide layer) is deposited over the resulting structure from the first step. Preferably, the dielectric layer 16 has a thickness of 10 nm to 1000 nm.

In a third step, an area where the step-like portion 172 with two or more step portions to be formed is defined on a portion of the dielectric layer 16 covering a left portion of the lightly doped n-type drain region 12 using photoresist.

Preferably, the distance S2 between the left edge of the step-like portion 172 and the nearest edge of the polysilicon gate 15 is 0.001 μm to 0.3 μm.

In a fourth step, a portion of the dielectric layer 16 that covers a left portion of the lightly doped n-type drain region 12 is etched into a step-like structure with two or more step portions increasing their height from the left to the right.

FIG. 4 shows an embodiment of the step-like structure with two step portions, whilst FIG. 5 shows another embodiment of the step-like structure with three step portions.

Preferably, the first step portion that is nearest to the polysilicon gate 15 has a thickness T0 of 10 nm to 800 nm; portions of the dielectric layer below two adjacent step portions have a thickness difference of 10 nm to 100 nm; and each step portion has a length (e.g., in the embodiment of FIG. 5, the first step portion has a length L1, the second step portion has a length L2, and the third step portion has a length L3) of 0.01 μm to 3 μm.

In a fifth step, the photoresist is removed and a metal layer is deposited over the resulting structure. Preferably, the metal layer has a thickness of 0.01 μm to 3 μm.

In a sixth step, a portion of the metal layer is removed using a photolithography and etching process such that the rest portion that covers a right portion of the polysilicon gate 15 and the entire step-like structure serves as the Faraday shield 17. Preferably, the portion of the remaining portion of the metal layer that covers the right portion of the polysilicon gate 15 has a length Si of 0 μm to 1 μm.

In a seventh step, subsequent processes are carried out to complete the RF LDMOS device.

### Embodiment 4

In this embodiment, the first step of the method of Embodiment 3 includes the following steps:

1) growing the p-type epitaxial layer 10 over a p-type substrate;

2) forming the p-type well 11 in the p-type epitaxial layer 10 by p-type ion implantation followed by high-temperature drive-in (i.e., ion activation);

3) growing the gate oxide layer 14 over the p-type epitaxial layer 10;

4) depositing polysilicon over the gate oxide layer 14;

5) defining an area where the polysilicon gate 15 is to be formed using photoresist in such a manner that a left portion of the defined area covers a right portion of the p-type well 11, and removing a portion of each of the gate oxide layer 14 and polysilicon 15 deposited out of the defined area;

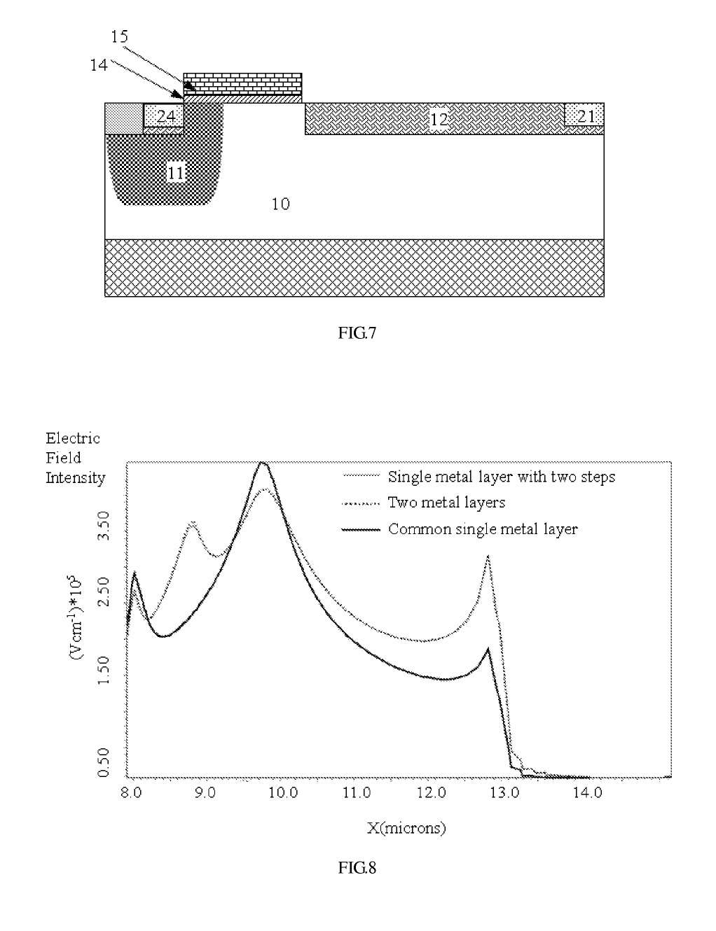

6) as shown in FIG. 7, performing a light n-type ion implantation with photoresist in the defined area remaining on top of the formed polysilicon gate 15 to form the lightly doped n-type drain region 12 in an upper right portion of the p-type epitaxial layer 10 and a lightly doped n-type source region 18 in an upper portion of the p-type well 11 left to the polysilicon gate 15; and

7) defining areas where a heavily doped n-type source region 24 and a heavily doped n-type drain region 21 are to be formed, respectively, using photolithography and forming the heavily doped n-type source region 24 right to the lightly doped n-type source region 18 and the heavily doped n-type drain region 21 in a right portion of the lightly doped n-type drain region 12 using n-type ion implantation.

In a breakdown voltage measurement carried out to an RF LDMOS device constructed in accordance with the present invention, the metal layer of the Faraday shield, the source and the gate of the device are all grounded and a drain voltage is scanned. In this set-up, the metal layer functions as a field plate, which causes an electric field at a surface under an edge of the step-like portion of the metal layer to be increased, thereby resulting in reduction of an electric field around an edge of the gate. FIG. 8 depicts electric field intensity curves of a common Faraday shield comprised of a single metal layer, a common Faraday shield comprised of two metal layers and a Faraday shield comprised of a step-like metal layer with two step portions of the present invention. In the figure, the horizontal coordinates 8.0 μm and 13.0 μm correspond to a right edge of the polysilicon gate and a left edge of the heavily doped n-type drain region, respectively, and vertical coordinates indicate electric field intensities at different positions on a top surface of the lightly doped n-type drain region. Moreover, the area enclosed by each curve is equal to the breakdown voltage of a corresponding device. As can be seen from the figure, each curve has several peaks indicating high electric field intensities at corresponding positions. Among the peaks, the left-most one corresponds to an area around a bottom edge of the polysilicon gate, the right-most one is caused by heavy doping of the drain region, and the middle one (ones) is originated from the Faraday shield. The curve of the common Faraday shield comprised of a single metal layer has only one middle peak and the area enclosed by the curve is relatively small, indicating a low breakdown voltage of the corresponding RF LDMOS device. Moreover, the left-most peak of the curve is relatively high which indicates high electric field intensity around the bottom edge of the polysilicon gate and a low reliability of the corresponding device. On the contrary, both of the rest two curves have two middle peaks and a large enclosed area, which indicates both of the corresponding RF LDMOS devices have a high breakdown voltage. In addition, the left-most peak of each of these two curves is low, which indicates low electric field intensity around the bottom edge of the polysilicon gate and a high reliability of the corresponding device.

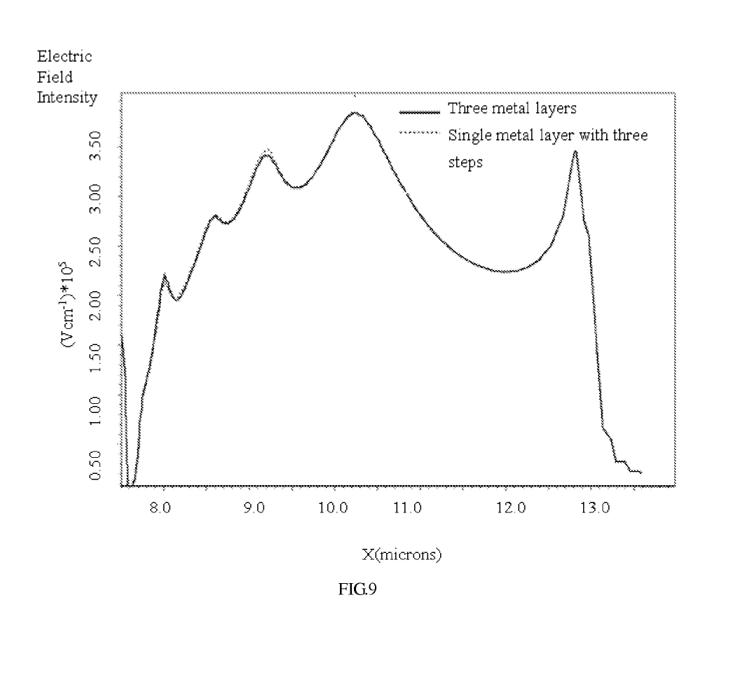

FIG. 9 depicts electric field intensity curves of a common Faraday shield comprised of three metal layers and a Faraday shield comprised of a step-like metal layer with three step portions of the present invention. Similarly, in the figure, the horizontal coordinates 8.0 μm and 13.0 μm correspond to a right edge of the polysilicon gate and a left edge of the heavily doped n-type drain region, respectively, and vertical coordinates indicate electric field intensities at different positions on a top surface of the lightly doped n-type drain region. With reference to the figure in conjunction with the above description of the indication of the left-most peak, both the corresponding RF LDMOS devices to these two curves have low electric field intensity around the bottom edge of the polysilicon gate. Moreover, as can be seen from the figure, each corresponding RF LDMOS device has three high electric field intensity areas in its drift region and a higher breakdown voltage.

The Faraday shield formed of a single metal layer with a step-like shape enables the RF LDMOS device of the present invention to have a similar performance with an RF LDMOS device employing a Faraday shield formed of multiple metal layers in attaining a high breakdown voltage while keeping the on-resistance and gate-drain capacitance unchanged. Moreover, compared to the complicated fabrication of the Faraday shield formed of multiple metal layers, the Faraday shield formed of a single metal layer with a step-like shape of the present invention can be fabricated in a simpler way which results in the elimination of at least one dielectric layer deposition process, one metal layer deposition process and one metal etching processes. Therefore, the present invention not only ensures a high breakdown voltage and a high reliability for an RF LDMOS device, but also enables the device to be fabricated in a simple way.

While preferred embodiments are described and illustrated herein, they are not intended to limit the invention in any way. Various alternatives, modifications and variations may be made without departing from the scope of the invention. Thus, it is intended that the present invention embraces all such alternatives, modifications and variations as fall within the true scope of the invention.

What is claimed is:

1. A radio frequency (RF) laterally diffused metal oxide semiconductor (LDMOS) device, comprising:
a substrate;
a p-type epitaxial layer on the substrate;
a p-type well in a first portion of the p-type epitaxial layer;
a lightly doped n-type drain region in a second portion of the p-type epitaxial layer and separated from the p-type well;
a gate oxide layer covering a portion of the p-type well and a portion of the p-type epitaxial layer between the p-type well and the lightly doped n-type drain region;
a polysilicon gate covering the gate oxide layer;
a dielectric layer covering the polysilicon gate and a portion of the lightly doped n-type drain region; and
a Faraday shield formed of a single metal layer and comprising:
a horizontal portion covering a portion of the polysilicon gate and isolated from the polysilicon gate by the dielectric layer;
a step-like portion covering a portion of the lightly doped n-type drain region and isolated from the lightly doped n-type drain region by the dielectric layer, the step-like portion having a step-like top surface with at least two step portions and a height of the at least two step portions increasing progressively in a direction from the p-type well to the lightly doped n-type drain region; and
a vertical portion connecting the horizontal portion with the step-like portion, the vertical portion being isolated from the polysilicon gate and the lightly doped n-type drain region by the dielectric layer.

2. The RF LDMOS device according to claim 1, wherein the step-like portion has a step-like top surface with two step portions and a height of the two step portions increases progressively in a direction from the p-type well to the lightly doped n-type drain region.

3. The RF LDMOS device according to claim 1, wherein the step-like portion has a step-like top surface with three step portions and a height of the three step portions increases progressively in a direction from the p-type well to the lightly doped n-type drain region.

4. The RF LDMOS device according to claim 1, wherein a portion of the dielectric layer between a first step portion nearest to the gate oxide layer and the lightly doped n-type drain region has a thickness of 10 nm to 800 nm, wherein a portion of the dielectric layer between a former step portion and the lightly doped n-type drain region has a thickness of 10 nm to 100 nm smaller than a thickness of a portion of the dielectric layer between a latter step portion and the lightly doped n-type drain region, and wherein each step portion of the step-like portion has a length of 0.01 μm to 3 μm.

5. The RF LDMOS device according to claim 1, wherein a portion of the dielectric layer between the vertical portion and the polysilicon gate has a thickness of 0.001 μm to 0.3 μm.

6. The RF LDMOS device according to claim 1, wherein the horizontal portion has a length of 0 μm to 1 μm.

7. The RF LDMOS device according to claim 1, further comprising:
a heavily doped n-type source region in an upper portion of the p-type well; and
a heavily doped n-type drain region in the lightly doped n-type drain region and proximate to an edge of the lightly doped n-type drain region that is farther from the gate oxide layer,
wherein both the heavily doped n-type source region and the heavily doped n-type drain region have an n-type dopant concentration higher than an n-type dopant concentration of the lightly doped n-type drain region.

8. A method of fabricating a radio frequency (RF) laterally diffused metal oxide semiconductor (LDMOS) device, comprising the steps of:
providing a substrate;
forming a p-type epitaxial layer over the substrate;
forming a p-type well in a first portion of the p-type epitaxial layer;
forming a lightly doped n-type drain region in a second portion of the p-type epitaxial layer, the lightly doped n-type drain region being separated from the p-type well;
forming a gate oxide layer and a polysilicon gate, the gate oxide layer covering a portion of the p-type well and a portion of the p-type epitaxial layer between the p-type well and the lightly doped n-type drain region, the polysilicon gate covering the gate oxide layer;
depositing a dielectric layer over the polysilicon gate and a portion of the lightly doped n-type drain region; and
forming a Faraday shield, the Faraday shield including:
a horizontal portion covering a portion of the polysilicon gate and isolated from the polysilicon gate by the dielectric layer;
a step-like portion covering a portion of the lightly doped n-type drain region and isolated from the lightly doped n-type drain region by the dielectric layer, the step-like portion having a step-like top surface with at least two step portions and a height of the at least two step portions increasing progressively in a direction from the p-type well to the lightly doped n-type drain region; and
a vertical portion connecting the horizontal portion with the step-like portion, the vertical portion being isolated from the polysilicon gate and the lightly doped n-type drain region by the dielectric layer.

9. The method according to claim 8, wherein a portion of the dielectric layer between a first step portion nearest to the gate oxide layer and the lightly doped n-type drain region has a thickness of 10 nm to 800 nm, wherein a portion of the dielectric layer between a former step portion and the lightly doped n-type drain region has a thickness of 10 nm to 100 nm smaller than a thickness of a portion of the dielectric layer between a latter step portion and the lightly doped n-type drain region, and wherein each step portion of the step-like portion has a length of 0.01 μm to 3 μm.

10. The method according to claim 8, wherein a portion of the dielectric layer between the vertical portion and the polysilicon gate has a thickness of 0.001 μm to 0.3 μm.

11. The method according to claim 8, wherein the horizontal portion has a length of 0 μm to 1 μm.

12. The method according to claim 8, wherein the step-like portion has a step-like top surface with two step portions and a height of the two step portions increases progressively in a direction from the p-type well to the lightly doped n-type drain region.

13. The method according to claim 8, wherein the step-like portion has a step-like top surface with three step portions and a height of the three step portions increases progressively in a direction from the p-type well to the lightly doped n-type drain region.

14. The method according to claim 8, further comprising the steps of:
forming a heavily doped n-type source region in an upper portion of the p-type well; and
forming a heavily doped n-type drain region in the lightly doped n-type drain region and proximate to an edge of the lightly doped n-type drain region that is farther from the gate oxide layer,
wherein both the heavily doped n-type source region and the heavily doped n-type drain region have an n-type dopant concentration higher than an n-type dopant concentration of the lightly doped n-type drain region.
